(19) United States
(12) Patent Application Publication
(10) Pub. No.: US 2021/0384463 A1
(43) Pub. Date: Dec. 9, 2021

(54) DISPLAY PANEL, MANUFACTURING METHOD THEREOF AND DISPLAY MODULE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Tianfu GUO, Wuhan, Hubei (CN); Hsianglun HSU, Wuhan, Hubei (CN)

(21) Appl. No.: 16/498,007

(22) PCT Filed: Nov. 15, 2018
(86) PCT No.: PCT/CN2018/115536

§ 371 Date: Sep. 26, 2019

(30) Foreign Application Priority Data
Oct. 15, 2018 (CN) 201811196756.2

(51) Int. Cl. H01L 51/52; H01L 51/56

(52) U.S. Cl. CPC H01L 51/5253; H01L 27/3246; H01L 51/56

(57) ABSTRACT

The present disclosure provides a display panel, a manufacturing method of the display panel, and a display module. The display panel includes a packaging layer including a plurality of packaging units arranged in an array. A blocker is disposed between the two adjacent packaging units. At least one inorganic layer and at least one organic layer are disposed between two of the adjacent blockers. At least one display unit is correspondingly disposed between two of the adjacent blockers.

### FIELD OF INVENTION

The present disclosure relates to a field of displays, particularly to a display panel, a manufacturing method of the display panel, and a display module including the display panel.

### BACKGROUND OF INVENTION

In display panel technology, an organic light emitting diode (OLED) display has advantages such as being light in weight, being self-luminous, quick response times, wide viewing-angles, wide display colors, being highly illuminous, low power consumption, etc. The OLED display becomes a third generation display technology after liquid crystal displays.

At present, a film packaging layer of the OLED is utilized to block water and air. The film packaging layer usually includes a dense inorganic layer as a layer to block water and air. However, the inorganic layer limits the development of thin film encapsulation (TFE) technology due to its high inner pressure and being easy-broken and hard-flexed.

Hence, a display panel is required for solving the above-mentioned problems.

### SUMMARY OF INVENTION

The present disclosure provide a display panel, a manufacturing method of the display panel, and a display module to solve the problem cause from high inner-pressure of a thin film packaging layer of present display panel.

To solve the above-mentioned problems, the present disclosure provides the following solutions.

The present disclosure provides a display panel comprising:

an array substrate;

a pixel defining layer disposed on the array substrate and comprising a plurality of first openings;

a light-emitting layer disposed on the array substrate and comprising a display unit, wherein each display unit is disposed in the first opening; a packaging layer disposed on the light-emitting layer and comprising at least two packaging units, wherein a blocker is disposed between two of the adjacent packaging units;

wherein at least one inorganic layer and at least one organic layer are disposed between two of the adjacent blockers, and at least one of the display unit is correspondingly disposed between two of the adjacent blockers.

In the display panel of the present disclosure, an orthographic projection of the blocker on the pixel defining layer is on the pixel defining layer between two of the adjacent first opening.

In the display panel of the present disclosure, the packaging layer comprises a first inorganic layer disposed on the light-emitting layer, a first organic layer disposed on the first inorganic layer, and a second inorganic layer disposed on the first organic layer; wherein the first inorganic layer and the first organic layer are disposed between two of the adjacent blockers.

In the display panel of the present disclosure, the second inorganic layer comprises at least two second inorganic units arranged in array and comprises grooves crisscrossed for isolating the second inorganic units from each other.

In the display panel of the present disclosure, the packaging layer further comprises a third inorganic layer disposed between the blockers and the second inorganic layer, where the third inorganic layer and the first organic layer are formed in the same process.

In the display panel of the present disclosure, a shape of the blocker is inverse trapezoid or inverse triangle.

In the display panel of the present disclosure further comprises a first protection layer disposed between the blocker and the light-emitting layer.

In the display panel of the present disclosure, the packaging layer further comprises a second protection layer disposed on a surface of the blocker; wherein the second protection layer is formed by an inorganic film layer or a metal film.

The present disclosure further provides a manufacturing method for a display panel comprising:

providing an array substrate;

disposing a pixel defining layer on the array substrate;

the pixel defining layer comprises a plurality of first openings;

disposing a light-emitting layer on the array substrate;

the light-emitting layer comprises a display unit disposed in the first opening;

disposing a packaging layer on the light-emitting layer;

wherein the packaging layer comprises at least two packaging units, a blocker is disposed between two of the adjacent packaging units, at least one inorganic layer and at least one organic layer are disposed between two of the adjacent blockers, and at least one of the display unit is correspondingly disposed between two of the adjacent blockers.

In the manufacturing method of the present disclosure, disposing the packaging layer on the light-emitting layer comprises:

forming at least two of the blockers on the light-emitting layer;

an orthographic projection of the blocker on the pixel defining layer is disposed between two of the adjacent first openings and disposed in the pixel defining layer;

depositing a inorganic film layer between the blockers and the light-emitting layer to form the first inorganic layer and a third inorganic layer;

the first inorganic layer is disposed between two of the adjacent blockers and disposed on the light-emitting layer, the third inorganic layer is disposed on the blocker;

disposing a first organic layer between two of the adjacent blockers,

a thickness of the blocker or the third inorganic layer is less or equal to a thickness of the first inorganic layer and the first organic layer;

disposing a second inorganic layer on the first organic layer and the third inorganic layer;

wherein the second inorganic layer comprises at least two second inorganic units arranged in array and comprises grooves crisscrossed for isolating the second inorganic units from each other, an orthographic projection of the grooves on the blocker is located in the blocker.

In the manufacturing method of the present disclosure, the display panel further comprises a first protection layer disposed between the blocker and the light-emitting layer.

In the manufacturing method of the present disclosure, the packaging layer further comprises a second protection layer disposed in a surface of the blocker; wherein the second protection layer is formed by an inorganic film layer or a metal film.

The present disclosure further provides a display module comprising a display panel, a touch layer, a polarizing layer and a cover layer, where the touch layer, the polarizing layer and the cover layer are disposed on the display panel, wherein the display panel comprises:

an array substrate;

a pixel defining layer disposed on the array substrate and comprising a plurality of first openings;

a light-emitting layer disposed on the array substrate and comprising a display unit, wherein each display unit is disposed in the first opening;

a packaging layer disposed on the light-emitting layer and comprising at least two packaging units, wherein a blocker is disposed between two of the adjacent packaging units;

wherein at least one inorganic layer and at least one organic layer are disposed between two of the adjacent blockers, at least one of the display unit is correspondingly disposed between two of the adjacent blockers

In the display module of the present disclosure, an orthographic projection of the blocker on the pixel defining layer is on the pixel defining layer between two of the adjacent first openings.

In the display module of the present disclosure, the packaging layer comprises a first inorganic layer disposed on the light-emitting layer, a first organic layer disposed on the first inorganic layer, and a second inorganic layer disposed on the first organic layer; wherein the first inorganic layer and the first organic layer are disposed between two of the adjacent blockers.

In the display module of the present disclosure, the second inorganic layer comprises at least two second inorganic units arranged in array and comprises grooves crisscrossed for isolating the second inorganic units from each other.

In the display module of the present disclosure, the packaging layer further comprises a third inorganic layer disposed between the blockers and the second inorganic layer, where the third inorganic layer and the first organic layer are formed in the same process; wherein a thickness of the blocker or the third inorganic layer is less or equal to a thickness of the first inorganic layer and the first organic layer.

In the display module of the present disclosure, a shape of the blocker is inverse trapezoid or inverse triangle.

In the display module of the present disclosure further comprises a first protection layer disposed between the blocker and the light-emitting layer

In the display module of the present disclosure, the packaging layer further comprises a second protection layer disposed on a surface of the blocker; wherein the second protection layer is formed by an inorganic film layer or a metal film.

### DESCRIPTION OF DRAWINGS

The drawings required for describing the embodiments or present solutions are introduced for the purpose of making the technical solutions in the embodiments of the present invention clear and completely described. Obviously, the described embodiments are only some of the embodiments of the present invention. Other embodiments which can be obtained by a person having ordinary skill in the art without any creative effort on the basis of the embodiments of the present invention shall fall within the scope of the present disclosure.

FIG. 1 illustrates a layered structure of a display panel of a first embodiment of the present disclosure.

FIG. 2 illustrates a top view of a packaging layer of the display panel of the first embodiment of the present disclosure.

FIG. 3 illustrates a layered structure of a display panel of a second embodiment of the present disclosure.

FIG. 4 illustrates a layered structure of a blocker of a display panel of a third embodiment.

FIG. 5 illustrates a layered structure of a display panel of a fourth embodiment of the present disclosure.

FIG. 6 illustrates a first part of a manufacturing method of the display panel of the present disclosure.

FIGS. 7A-7J illustrates technical flows for manufacturing the display panel of the present disclosure.

FIG. 8 illustrates a second part of the manufacturing method of the display panel of the present disclosure.

### DETAILED DESCRIPTION OF PREFERRED EMBODIMENTS

The illustrations of the following embodiments take the attached drawings as reference to indicate the applicable specific examples of the present disclosure. The mentioned directional terms, such as upper, lower, front, back, left, right, inner, outer, side, etc., are only directions by referring to the accompanying drawings, and thus the used directional terms are used to describe and understand the present invention, but the present invention is not limited thereto. In the drawings, similar modules are numbered with the same reference numbers.

Please refer to FIG. 1, which illustrates a layered structure of a display panel of an embodiment of the present disclosure.

The display panel includes an array substrate 10, a pixel defining layer 20, a light-emitting layer 30, and a packaging layer 40.

The array substrate 10 includes a substrate 101 and a thin-film transistor (TFT) layer 102 disposed on the substrate 101.

In this embodiment, the substrate 101 can be made from glass substrates, quartz substrates or resin substrates.

In this embodiment, structures of the TFT layer 102 can be made in, but not limited to, an etch stop layer type, a back channel etch type, or a top-gate TFT type. Take top-gate TFT type as an example. The TFT layer includes a buffer layer, an active layer, a gate insulation layer, a gate layer, an inter-insulation layer, a source-drain layer, and a planarization layer.

The pixel defining layer 20 is disposed on the array substrate 10 for dividing adjacent pixel units 304 of the display panel to avoid color mixing. The pixel defining layer 20 includes a plurality of first openings 201 corresponding to the display pixels units 304 one by one.

The light-emitting layer 30 is disposed on the array substrate 10. The light emitting layer 30 includes an anode layer 301 disposed on the array substrate 10, an emitting layer 302 disposed on the anode layer 301, and a cathode layer 303 disposed on the emitting layer 302.

The anode layer 301 includes a plurality of anode electrodes 3011 arranged in an array. Each of the plurality of anode electrodes 3011 corresponds to each of the first openings 201 one by one. The emitting layer 302 includes a plurality of emitting units 3021 which correspond to the anode electrodes 3011 one by one.

The light-emitting layer 30 includes the plurality of anode electrodes 3011, emitting units 3021, and display units 304 formed on a cathode layer 303. The display units 304 are red sub-pixels, green sub-pixels or blue sub-pixels. The colors of two adjacent display units are different.

The packaging layer 40 is disposed on the cathode layer 303. The packaging layer 40 is utilized to protect a non-film layer structure of the display layer from being intruded by water in the air.

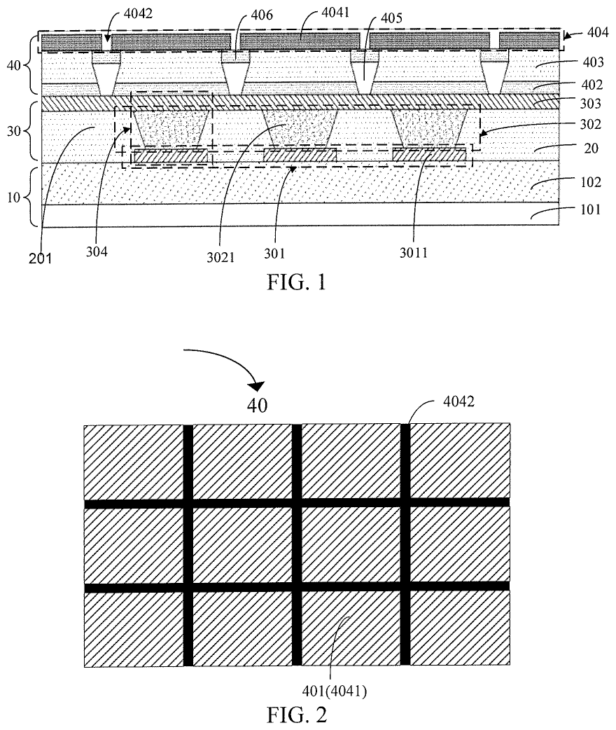

Please refer to FIG. 2, which illustrates a top view of the packaging layer of the display panel of this embodiment.

The packaging layer 40 includes a plurality of packaging units 401 arranged in an array. Each of the packaging units 401 includes at least one organic layer and at least one inorganic layer stacked crossed each other to ensure quality of blocking water and oxygen. In the meanwhile, the flexibility of the packaging layer 40 is improved.

In one of the embodiments, the organic layer is disposed in the middle of the packaging layer and disposed between two inorganic layers.

Each of the packaging units 401 corresponds to at least one of the display units 304.

Pleases refer to FIG. 1. The packaging unit 401 includes a first inorganic layer 402, a first organic layer 403, and a second inorganic layer 404. The first organic layer 403 is disposed between the first inorganic layer 402 and the second inorganic layer 404.

A blocker 405 is disposed between the two adjacent packaging units 401. At least one organic layer and at least one inorganic layer are disposed between two adjacent blockers.

At least one of the display units 304 is correspondingly disposed between the two adjacent blockers 405.

Please refer to FIG. 1. The display unit 304 is correspondingly disposed between the two adjacent blockers 405.

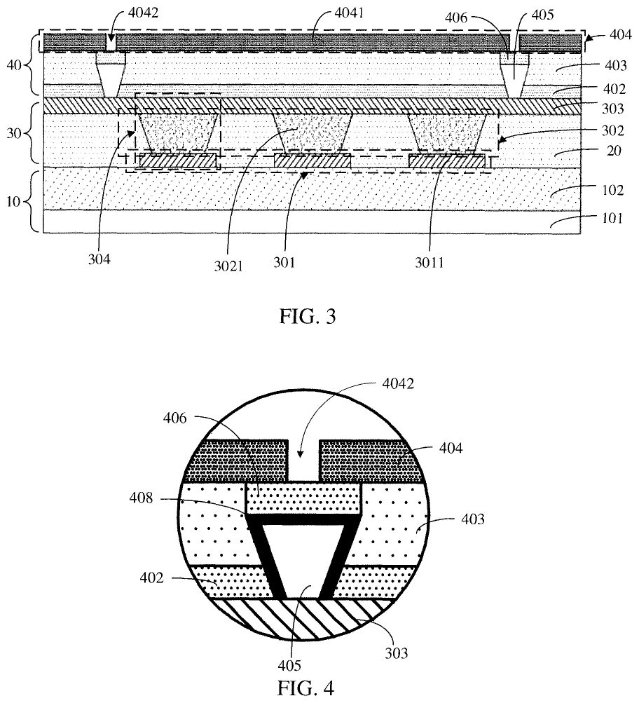

Please refer to FIG. 3. There are three display units 304 correspondingly disposed between the two adjacent blockers 405.

The blockers are disposed on the cathode layer 303. In the display panel of the present disclosure, an orthographic projection of the blockers 405 on the pixel defining layer 20 correspondingly falls between the two adjacent first opening 201.

The blockers 405 are formed in the non-display area of the display panel. Thus, the blockers 405 do not affect an aperture ratio of the display panel.

The packaging layer 40 further includes a third inorganic layer 406 disposed on the blockers 405.

In one of the embodiments, the third inorganic layer 406 is disposed between the blockers 405 and the second inorganic layer 404.

In one embodiment, the third inorganic layer 406 and the first inorganic layer 402 are formed in the same process. After forming the blockers 405 on the light-emitting layer, an inorganic layer is deposited on the blockers 405 and the cathode layer 303 of the light-emitting layer 30. In the meanwhile, the first inorganic layer 402 is formed between the two adjacent blockers 405 and the third inorganic layer 406 is formed on the blockers 405.

In one of the embodiments, material of the first inorganic layer 402 and the third inorganic layer 406 can be at least one of silicon nitride, SiON, Al2O3, TiO2, and any kind of inorganic water-blocking layers.

A thickness of the blockers 405 is not greater than a thickness of the first organic layer 403.

In one of the embodiments, the thickness of the blockers 405 is equal to the thickness of the first organic layer 403. Material of the second inorganic layer 404 is the same as material of the first inorganic layer 402 or material of the third inorganic layer 406.

Please refer to FIG. 2. The second inorganic layer 404 includes at least two second inorganic units 4041 arranged in an array and grooves 4042 being crisscrossed for isolating the second inorganic units 4041. An orthographic projection of the grooves 4042 on the blockers 405 falls within an area of the blockers 405.

The cross-sectional view of the blockers 405 are inverted trapezoids or inverted triangles.

Please refer to FIG. 1 or FIG. 3. In these embodiments, the cross-sectional view of the blockers 405 are inverted trapezoids.

In one of the embodiments, the thickness of the blockers is 1-20 μm.

In one of the embodiments, the blockers contain an inorganic material.

Please refer to FIG. 4, which illustrates a layered structure of the blockers of the display panel of a third embodiment of the present disclosure.

In order to protect the organic layer of the light-emitting layer 30 from being harmed by a photolithography process performed on the packaging layer 40, a surface of the blockers 405 includes a second protection layer 408.

In one of the embodiments, material of the second protection layer is the same as the inorganic material contained in the packaging layer 40.

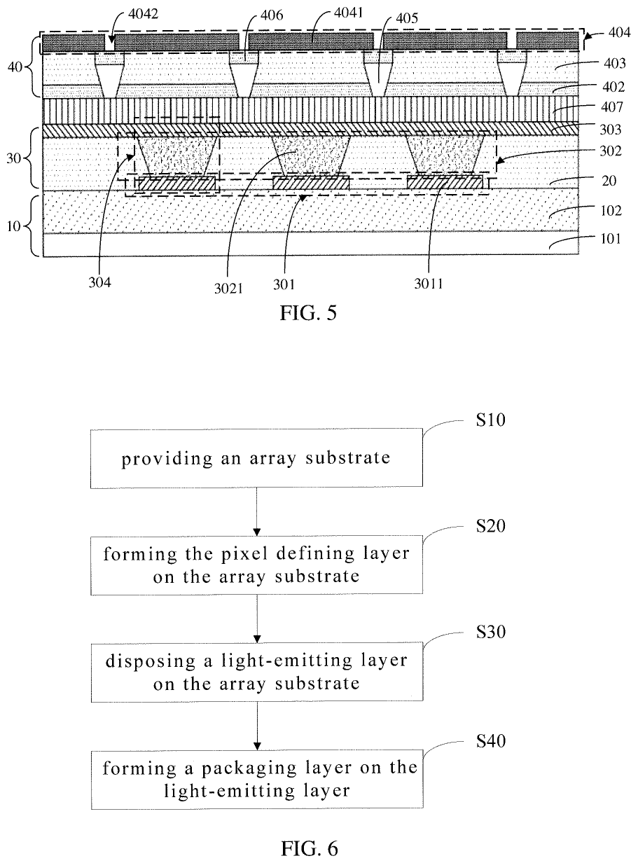

Please refer to FIG. 5, which illustrates a layered structure of a fourth embodiment of the present disclosure.

In order to improve the water and oxygen protection of the packaging layer 40, the display panel further includes a first protection layer 407 disposed between the blockers 405 and the light-emitting layer.

In one of the embodiments, material of the first protection layer 407 can be an inorganic layer or a metal layer.

In order to further improve the protection of the packaging layer 40 from water and oxygen, two more layers can be disposed between the two adjacent blockers. The layers can be organic layers or inorganic layers.

Internal stress of the packaging layer is reduced by disposing one of the blockers 405 on the package because the packaging layer can be individually packaged due to an organic-inorganic cross-stack layer between the two adjacent blockers. Therefore, the packaging layer becomes more flexible.

Please refer to FIG. 6, which illustrates processes for manufacturing the display panel of the present disclosure.

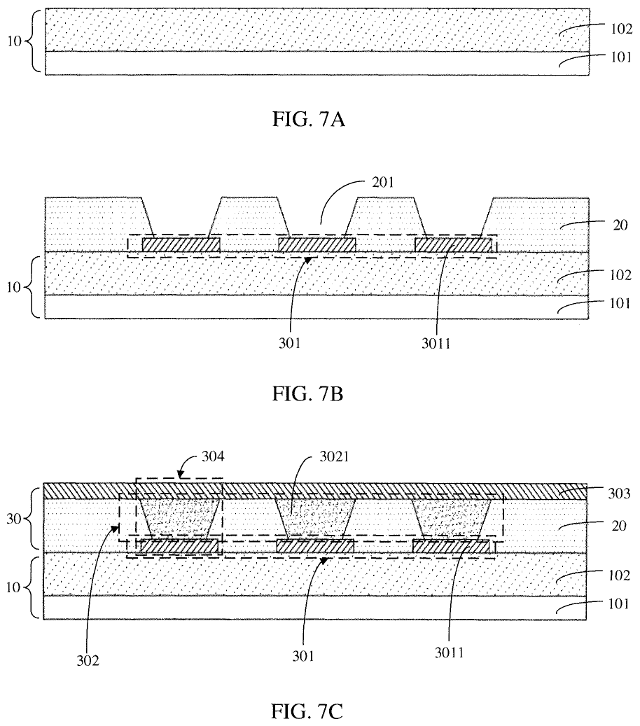

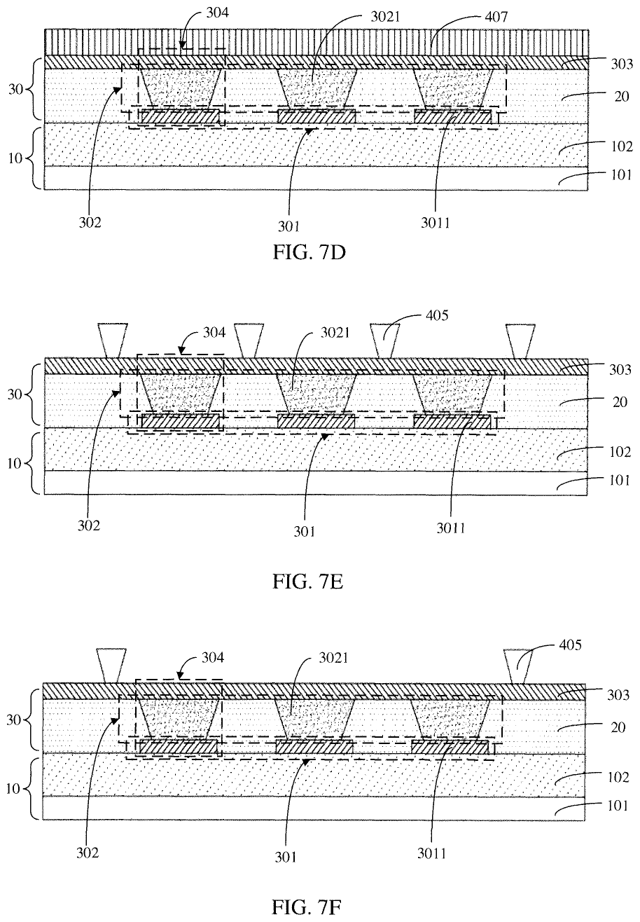

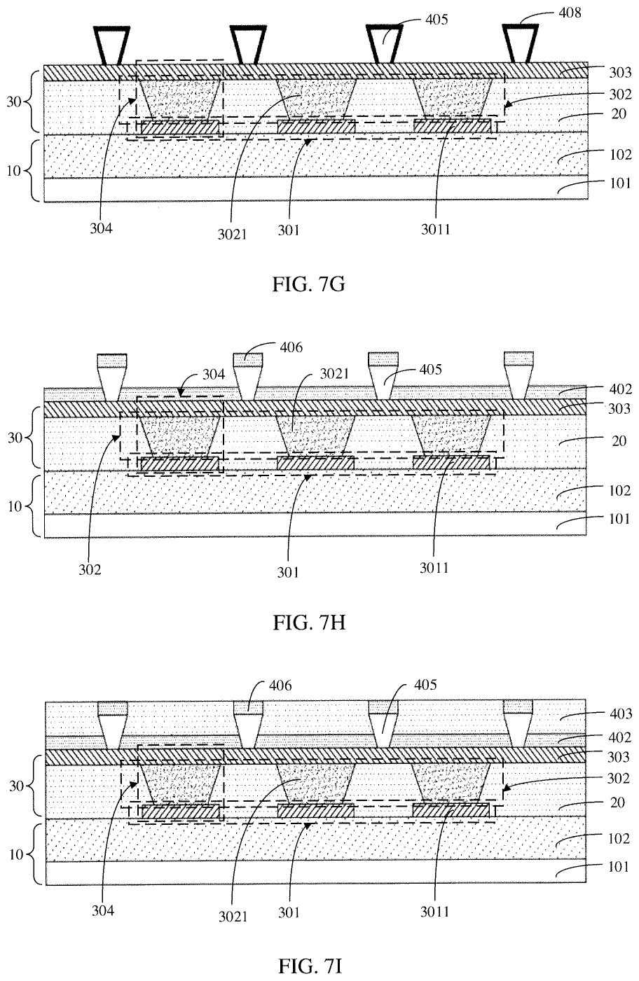

Please refer to FIG. 7. FIGS. 7A-7J illustrate technical flows for manufacturing the display panel of the present disclosure.

The method for manufacturing the display panel has the following steps.

S10: providing an array substrate 10.

Please refer to FIG. 7A. In this step, the substrate 101 is provided and the TFT layer 102 is disposed on the substrate 101.

In one of the embodiments, the substrate 101 can be a glass substrate, quartz substrate, resin substrate, or any other kinds of substrates.

The TFT layer 102 can be, but not limited to, an etch stop layer type, a back channel etch type, or a top-gate TFT type. Take top-gate TFT type as an example, the TFT layer includes a buffer layer, an active layer, a gate insulation layer, a gate layer, an inter-insulation layer, a source-drain layer, and a planarization layer.

S02: forming the pixel defining layer 20 on the array substrate 10.

Please refer to FIG. 7B, the pixel defining layer 20 is disposed on the array substrate 10. The plurality of first openings 201 are formed on the pixel defining layer 20 by photolithography technology. The first openings 201 correspond to the display units 304 one by one.

The step of forming the pixel defining layer 20 further includes a step of forming the anode layer 301 on the array substrate 10. The anode layer 301 includes a plurality of anode electrodes 3011 arranged in an array. Each of the plurality of anode electrodes 3011 corresponds to each of the first openings 201 one by one.

S30: disposing a light-emitting layer 30 on the array substrate 10.

Please refer to FIG. 7. The emitting layer 302 is formed in the first openings 201. The emitting layer 302 includes the plurality of emitting units 3021 which correspond to the anode electrodes 3011 one by one. The cathode layer 303 is formed on the emitting layer 302 and the pixel defining layer 20.

The light-emitting layer 30 includes a plurality of display units 304 formed in the first openings 201. The display units 304 include anode electrodes 3011 disposed on the array substrate 10, the emitting units 3021 disposed on the anode layer 301, and the cathode layer 303 disposed on the emitting units 302.

The display units 304 are red sub-pixels, green sub-pixels or blue sub-pixels.

Please refer to FIG. 7D. In order to protect the organic layer of the light-emitting layer 30 from being harmed by the photolithography process performed on the packaging layer, the surface of the blockers 405 includes the first protection layer 407.

Material of the second protection layer is the same as the inorganic material contained in the packaging layer.

S40: forming the packaging layer on the light-emitting layer 30.

The packaging layer includes a plurality of packaging units 401 arranged in an array. A blocker is disposed between two of the adjacent packaging units 401. At least one inorganic layer and at least one organic layer are disposed between two of the adjacent blockers 405. At least one of the display units 304 is correspondingly disposed between two of the adjacent blockers 405.

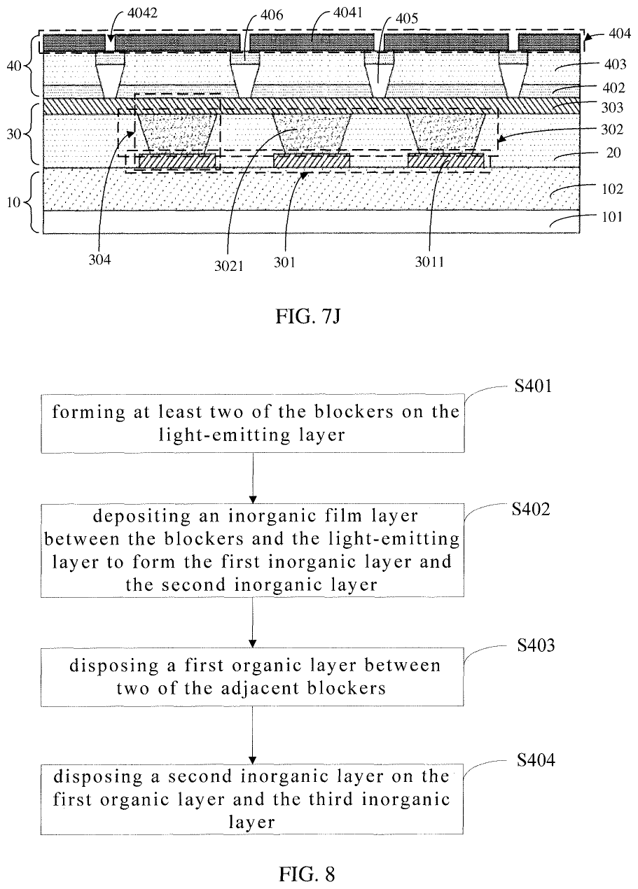

Please refer to FIG. 8, which illustrates the second step for manufacturing the display panel of the present disclosure.

S40 further comprises the following steps:

S401 of forming at least two of the blockers on the light-emitting layer 30.

One of the blockers 405 is disposed between two of the adjacent packaging units 401. At least one inorganic layer and at least one organic layer are disposed between two of the adjacent blockers.

At least one of the display units 304 is correspondingly disposed between two of the adjacent blockers 405.

In one of the embodiments, please refer to FIG. 7E. One of the display units 304 is correspondingly disposed between the two adjacent blockers 405.

In one of the embodiments, please refer to FIG. 7E. There are three of the display units 304 correspondingly disposed between the two adjacent blockers 405.

The cathode layer 303 is disposed on the blocker.

In one of the embodiments, the projection of the blocker 405 on the pixel defining layer 20 is disposed between two of the adjacent first openings 201 and disposed in the pixel defining layer 20.

In one of the embodiments, the blocker is formed in the non-display area of the display panel. Thus, the blocker does not affect the aperture ratio of the display panel.

The cross-sectional view of the blocker is an inverted trapezoid or an inverted triangle.

In one of the embodiments, the cros-sectional view of the blocker is an inverted trapezoid.

In one of the embodiments, the thickness of the blocker is 1-20 μm.

In one of the embodiments, the blocker contains an inorganic material.

Please refer to FIG. 7G. In order to improve the water and oxygen protection of the packaging layer, the display panel further includes a second protection layer 408 disposed between the blocker 405 and the light-emitting layer 30.

In one of the embodiments, material of the second protection layer 408 can be an inorganic layer or a metal layer.

S402: depositing an inorganic film layer between the blockers and the light-emitting layer to form the first inorganic layer 402 and the second inorganic layer 404.

Please refer to FIG. 7H. The second inorganic layer 404 and the first inorganic layer 402 are formed in the same process.

In one of the embodiments, material of the first inorganic layer 402 and the third inorganic layer 406 can be at least one of silicon nitride, SiON, Al2O3, TiO2, and any kinds of inorganic water-blocking layers.

S403: disposing the first organic layer 403 between two of the adjacent blockers.

Please refer to FIG. 7I. The first organic layer 403 is not higher than the third organic layer 406. The thicknesses of the blocker 405 and the third inorganic layer 406 are not greater than the thickness of the first inorganic layer 402 and the first organic layer 403.

In one of the embodiments, the thicknesses of the blocker 405 and the first organic layer 403 are the same.

S404: disposing the second inorganic layer 404 on the first organic layer 403 and the third inorganic layer 406.

Please refer to FIG. 7J. The second inorganic layer 404 convers the third inorganic layer 406 and the first organic layer 403, and is divided into the plurality of the second inorganic units 4041 by utilizing photolithography technology.

The crisscrossed grooves 4042 are disposed between two of the adjacent second inorganic units. An orthographic projection of the grooves 4042 on the blocker 405 falls within an area of the blocker 405.

In one of the embodiments, material of the second inorganic layer 404 is the same as material of the first inorganic layer 402 or the third inorganic layer 406.

Another aspect of the present disclosure further provides a display module including the above-mentioned display panel and a touch layer, a polarized layer, and a cover layer disposed accordingly. The packaging layer sticks on the touch layer via a first optical adhesive layer. The cover layer sticks on the polarized layer via a second optical adhesive layer.

Another aspect of the present disclosure further provides an electronic device including the above-mentioned display module. The electronic device includes, but not limited, a mobile phone, a pad, a calculator display, a game device, a television, a display screen, a portable device and other electronic devices which are capable to display.

The operating function of the display module and the electronic device can take the display panel of the present disclosure as reference.

The present disclosure provides a display panel, a manufacturing method of the display panel, and a display module. The display panel includes an array substrate, a pixel defining layer disposed on the array substrate and including first openings, a light-emitting layer disposed on the array substrate and including a display unit disposed in the first openings, and a packaging layer disposed on the light-emitting layer and including a blocker. At least one inorganic layer and at least one organic layer are disposed between two of the adjacent blockers, and at least one of the display units is correspondingly disposed between two of the adjacent blockers. Internal stress of the packaging layer is reduced by disposing the blockers on the package because the packaging layer can be individually packaged due to the organic-inorganic cross-stack layer between the two adjacent blockers. Therefore, the packaging layer becomes more flexible.

In conclusion, although this disclosure has been disclosed through the preferable embodiments above, the preferable embodiments above are not utilized to limit this disclosure. One having ordinary skills can change and modify without violating the concepts and scope of this disclosure. Therefore, the scope that this disclosure protects is based on the scope defined by the claims.

What is claimed is:

1. A display panel, comprising:
an array substrate;
a pixel defining layer disposed on the array substrate and comprising a plurality of first openings;
a light-emitting layer disposed on the array substrate and comprising a plurality of display units, wherein each of the display units is disposed in the first openings;
a packaging layer disposed on the light-emitting layer and comprising at least two packaging units, wherein a blocker is disposed between two of the adjacent packaging units;
wherein at least one inorganic layer and at least one organic layer are disposed between two of the adjacent blockers, and at least one of the display units is correspondingly disposed between two of the adjacent blockers.

2. The display panel according to claim 1, wherein an orthographic projection of the blockers on the pixel defining layer is on the pixel defining layer between two of the adjacent first openings.

3. The display panel according to claim 1, wherein the packaging layer comprises a first inorganic layer disposed on the light-emitting layer, a first organic layer disposed on the first inorganic layer, and a second inorganic layer disposed on the first organic layer;
wherein the first inorganic layer and the first organic layer are disposed between two of the adjacent blockers.

4. The display panel according to claim 3, wherein the second inorganic layer comprises at least two second inorganic units arranged in an array and comprises grooves crisscrossed for isolating the second inorganic units from each other.

5. The display panel according claim 3, wherein the packaging layer further comprises a third inorganic layer disposed between the blockers and the second inorganic layer, where the third inorganic layer and the first organic layer are formed in the same process.

6. The display panel according to claim 1, wherein a shape of the blockers is an inverted trapezoid or an inverted triangle:

7. The display panel according to claim 1 further comprises a first protection layer disposed between the blocker and the light-emitting layer.

8. The display panel according to claim 1, wherein the packaging layer further comprises a second protection layer disposed on a surface of the blocker;
wherein the second protection layer is formed by an inorganic film layer or a metal film.

9. A manufacturing method for a display panel, comprising:
providing an array substrate;
disposing a pixel defining layer on the array substrate;
the pixel defining layer comprises a plurality of first openings;
disposing a light-emitting layer on the array substrate;
the light-emitting layer comprises a plurality of display units disposed in the first opening;
disposing a packaging layer on the light-emitting layer;
wherein the packaging layer comprises at least two packaging units, a blocker is disposed between two of the adjacent packaging units, at least one inorganic layer and at least one organic layer are disposed between two of the adjacent blockers, and at least one of the display units is correspondingly disposed between two of the adjacent blockers.

10. The manufacturing method according to claim 9, wherein disposing the packaging layer on the light-emitting layer comprises:
forming at least two of the blockers on the light-emitting layer;
an orthographic projection of the blockers on the pixel defining layer is disposed between two of the adjacent first openings and disposed in the pixel defining layer;
depositing an inorganic film layer between the blockers and the light-emitting layer to form the first inorganic layer and a third inorganic layer;
the first inorganic layer is disposed between two of the adjacent blockers and disposed on the light-emitting layer, the third inorganic layer is disposed on the blocker;
disposing a first organic layer between two of the adjacent blockers,
a thickness of the blockers or the third inorganic layer is less or equal to a thickness of the first inorganic layer and the first organic layer;
disposing a second inorganic layer on the first organic layer and the third inorganic layer;
wherein the second inorganic layer comprises at least two second inorganic units arranged in an array and comprises grooves crisscrossed for isolating the second inorganic units from each other, an orthographic projection of the grooves on the blockers is located in the blockers.

11. The manufacturing method according to claim 9, wherein the display panel further comprises a first protection layer disposed between the blockers and the light-emitting layer.

12. The manufacturing method according to claim 9, wherein the packaging layer further comprises a second protection layer disposed in a surface of the blocker;
wherein the second protection layer is formed by an inorganic film layer or a metal film.

13. A display module comprising a display panel, a touch layer, a polarizing layer, and a cover layer, where the touch layer, the polarizing layer, and the cover layer are disposed on the display panel, wherein the display panel comprises:
an array substrate;
a pixel defining layer disposed on the array substrate and comprising a plurality of first openings;
a light-emitting layer disposed on the array substrate and comprising a plurality of display units, wherein each of the display units is disposed in the first openings;
a packaging layer disposed on the light-emitting layer and comprising at least two packaging units, wherein a blocker is disposed between two of the adjacent packaging units;
wherein at least one inorganic layer and at least one organic layer are disposed between two of the adjacent blockers, at least one of the display unit is correspondingly disposed between two of the adjacent blockers.

14. The display module according to claim 13, wherein an orthographic projection of the blocker on the pixel defining layer is on the pixel defining layer between two of the adjacent first openings.

15. The display module according to claim 13, wherein the packaging layer comprises a first inorganic layer disposed on the light-emitting layer, a first organic layer disposed on the first inorganic layer, and a second inorganic layer disposed on the first organic layer;
wherein the first inorganic layer and the first organic layer are disposed between two of the adjacent blockers.

16. The display module according to claim 15, wherein the second inorganic layer comprises at least two second inorganic units arranged in an array and comprises grooves crisscrossed for isolating the second inorganic units from each other.

17. The display module according claim 15, wherein the packaging layer further comprises a third inorganic layer disposed between the blockers and the second inorganic layer, where the third inorganic layer and the first organic layer are formed in the same process;
wherein a thickness of the blocker or the third inorganic layer is less or equal to a thickness of the first inorganic layer and the first organic layer.

18. The display module according to claim 13, wherein a shape of the blocker is an inverted trapezoid or an inverted triangle.

19. The display module according to claim 13 further comprises a first protection layer disposed between the blocker and the light-emitting layer.

20. The display module according to claim 13, wherein the packaging layer further comprises a second protection layer disposed on a surface of the blocker;
wherein the second protection layer is formed by an inorganic film layer or a metal film.
